(19) United States
(12) Patent Application Publication
(10) Pub. No.: US 2022/0416749 A1
(43) Pub. Date: Dec. 29, 2022

(54) FILTER DEVICE AND STEERING CONTROL DEVICE

(71) Applicant: MANDO CORPORATION, Gyeonggi-do (KR)

(72) Inventors: Jong Mu LEE, Gyeonggi-do (KR); Kyu Yeong JE, Gyeonggi-do (KR); Su Min LEE, Gyeonggi-do (KR)

(21) Appl. No.: 17/777,961

(22) PCT Filed: Nov. 18, 2020
(86) PCT No.: PCT/KR2020/016245

§ 371 Date: May 18, 2022

(30) Foreign Application Priority Data
Nov. 19, 2019 (KR) 10-2019-0148222

(51) Int. Cl. H03H 7/06; B62D 5/04

(52) U.S. Cl. CPC H03H 7/06; B62D 5/0463; B62D 5/0484

(57) ABSTRACT

The present embodiments relate to a filter device and a steering control device. The filter device filters noise by comprising a capacitor unit and a short-circuit prevention unit, wherein the capacitor unit and the short-circuit prevention unit are connected in series to each other, and when the capacitor unit is short-circuited, the short-circuit prevention unit may block a short-circuit current by changing impedance formed through the capacitor unit and the short-circuit prevention unit which are connected in series to each other.

### TECHNICAL FIELD

The present embodiments relate to a filter device and a steering control device.

### BACKGROUND ART

Generally, a steering system refers to a system that can change a steering angle of a wheel based on a steering force (or rotational force) that a driver of a vehicle has applied to a steering wheel. Recently, electric power steer (EPS), i.e., an electric power steering system has been applied to the vehicle in order to reduce the steering force of the steering wheel to ensure the stability of the steering state.

In particular, recently, when a battery cable is attached or detached in the electric power steering system, a printed circuit board (PCB) is subjected to bending force due to the applied force, which causes a problem in that elements of the filter device located near the battery connector may be damaged by an external force.

### DETAILED DESCRIPTION OF THE INVENTION

### Technical Problem

The present embodiments may provide a filter device capable of effectively preventing a short circuit.

Further, the present embodiments may provide a steering control device capable of effectively preventing a short circuit.

### Technical Solution

In one aspect, the present embodiments may provide a filter device for filtering noise, including a capacitor unit and a short-circuit prevention unit, wherein the capacitor unit and the short-circuit prevention unit are connected in series, and when the capacitor unit is short-circuited, the short-circuit prevention unit may block a short-circuit current by changing an impedance formed through the capacitor unit and the short-circuit prevention unit connected in series.

In another aspect, the present embodiments may provide a steering control device comprising a filter unit filtering noise of electrical energy; and a steering motor power supply unit converting the filtered electrical energy based on a steering motor control signal to generate an assist steering force, and controlling a steering motor based on the assist steering force, wherein the filter unit includes a capacitor unit and a short-circuit prevention unit, wherein the capacitor unit and the short-circuit prevention unit are connected in series, wherein when the capacitor unit is short-circuited, the short-circuit prevention unit may block a short-circuit current by changing an impedance formed through the capacitor unit and the short-circuit prevention unit connected in series.

### Advantageous Effects

According to the present embodiments, a filter device capable of effectively preventing a short circuit may be provided.

Further, according to the present embodiments, a steering control device capable of effectively preventing a short circuit may be provided.

### BRIEF DESCRIPTION OF DRAWINGS

FIG. 1 is an overall block diagram illustrating a filter device according to the present embodiments.

FIG. 2 is a detailed block diagram illustrating a capacitor unit and a short-circuit prevention unit according to the present embodiments.

FIGS. 3 to 5 are circuit diagrams specifically illustrating a filter device according to the present embodiments.

FIGS. 6 and 7 are diagrams specifically illustrating a resistor of a short-circuit prevention unit according to the present embodiments.

FIG. 8 is a detailed block diagram illustrating a steering control device according to the present embodiments.

FIG. 9 is an overall block diagram illustrating a steering system according to the present embodiments.

FIG. 10 is an overall flowchart illustrating a steering control method according to the present embodiments.

### MODE FOR CARRYING OUT THE INVENTION

Some embodiments of the present disclosure will be described in detail below with reference to exemplary drawings. In adding reference numerals to components of each drawing, the same components may have the same reference numerals as much as possible even though they are shown in different drawings. In addition, in describing the present embodiments, if it is determined that a detailed description of a related known configuration or function may obscure the gist of the present technical idea, the detailed description may be omitted. When “includes”, “has”, “consisting of”, etc. mentioned in this specification are used, other parts may be added unless “only” is used. If a component is expressed in a singular, it may include a plural unless otherwise explicitly stated.

Further, in describing the components of the present disclosure, terms such as “first”, “second”, “A”, “B”, “(a)”, “(b)”, etc. may be used. These terms are only for distinguishing the elements from other elements, and the essence, order, order, or number of the elements are not limited by the terms.

In the description of the positional relationship of the components, if it is described that two or more components are “connected”, “coupled” or “combined”, etc., two or more components are directly “connected”, “coupled” or “combined” ”, but it will be understood that two or more components may be “connected,” “coupled,” or “combined, ” with other components further “interposed”. Here, other components may be included in one or more of two or more components that are “connected”, “coupled” or “combined” to/with each other.

In the description of the temporal flow relationship related to the components, the operation method or the production method, if a temporal precedence or flow precedence is described as, for example, “after”, “following”, “followed by”, “before”, etc., it may include cases where it is not continuous unless “immediately” or “directly” is used.

On the other hand, in the case where numerical values or corresponding information (e.g., level, etc.) for components are mentioned, even if there is no separate explicit description, the numerical value or its corresponding information may be interpreted as including an error range that may occur due to various factors (e.g., process factors, internal or external shocks, noises, etc.).

Hereinafter, a filter device, a steering control device, and a steering system according to the present embodiments will be described with reference to the accompanying drawings.

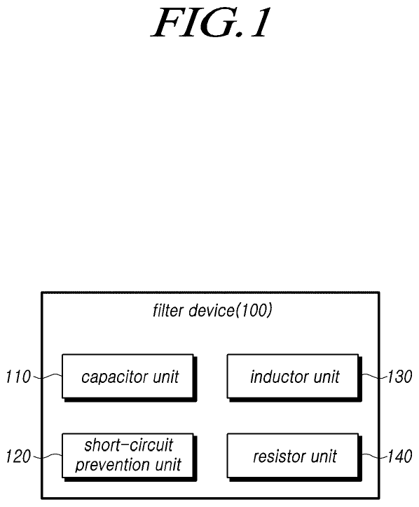

FIG. 1 is an overall block diagram illustrating a filter device according to the present embodiments.

Referring to FIG. 1, a filter device 100 according to the present embodiments may include at least one of a capacitor unit 110, a short-circuit prevention unit 120, an inductor unit 130, and a resistor unit 140. The capacitor unit 110, the short-circuit prevention unit 120, the inductor unit 130, and the resistor unit 140 may be connected by at least one of electrical, magnetic, and mechanical manners.

The capacitor unit 110 and the short-circuit prevention unit 120 may be one or more. Although the description will be made below with respect to a case in which the capacitor unit 110 and the short-circuit prevention unit 120 are one in number, the disclosure is not limited thereto and may be applied to a case in which the capacitor unit 110 and the short-circuit prevention unit 120 are two or more.

The filter device 100 may include the capacitor unit 110 and the short-circuit prevention unit 120 to filter noise, and the capacitor unit 110 and the short-circuit prevention unit 120 may be connected in series. When the capacitor unit 110 is short-circuited, the short-circuit prevention unit 120 may block a short-circuit current by changing an impedance formed through the capacitor unit 110 and the short-circuit prevention unit 120 connected in series.

Specifically, the filter device 100 may filter an electrical signal. For example, the filter device 100 may pass or block noise included in the electrical signal, that is, pass or block a signal in a specific frequency range. Here, the electrical signal may refer to electrical energy including current and/or voltage.

The capacitor unit 110 and the short-circuit prevention unit 120 may be connected to each other. For example, the capacitor unit 110 and the short-circuit prevention unit 120 may be connected in series. In other words, the capacitor unit 110 and the short-circuit prevention unit 120 may be positioned on the same voltage path or current path, and may be positioned to be connected to each other in a line.

When the capacitor unit 110 out of the capacitor unit 110 and the short-circuit prevention unit 120 connected in series is short-circuited to generate an overcurrent, i.e., a short-circuit current, the short-circuit prevention unit 120 may block the short-circuit current by changing the impedance formed through the capacitor unit 110 and the short-circuit prevention unit 120 connected in series. Here, the overcurrent, i.e., the short-circuit current, maybe a current capable of changing an initial impedance (or a first impedance) of the short-circuit prevention unit.

For example, when the capacitor unit 110 out of the series-connected capacitor unit 110 and short-circuit prevention unit 120 is short-circuited to generate an overcurrent, i.e., a short-circuit current, the short-circuit prevention unit 120 may block the short-circuit current by changing its impedance so that the impedance formed through the series-connected capacitor unit 110 and short-circuit prevention unit 120 may increase.

Here, the short-circuit prevention unit 120 may be fused after its impedance gradually increases with respect to the first impedance.

In particular, the first impedance may be the impedance of the short-circuit prevention unit 120, when the series-connected capacitor unit 110 and short-circuit prevention unit 120 are normal, that is, when the capacitor unit 110 is not short-circuited. Accordingly, when the series-connected capacitor unit 110 and short-circuit prevention unit 120 are normal, that is, when the capacitor unit 110 is not short-circuited, the filter device 100 may remove noise through the capacitor unit 110, and the short-circuit prevention unit 120 with the first impedance, which are connected in series.

As described above, the filter device according to the present embodiments may perform a filtering operation through the capacitor unit and the short-circuit prevention unit, when it is in a normal state. Alternatively, when the capacitor unit is short-circuited to generate a short-circuit current, the short-circuit prevention unit maybe fused after the impedance of the short-circuit prevention unit gradually increases with respect to the first impedance which is the normal-state impedance. As a result, the voltage path or current path of the series-connected capacitor unit and short-circuit prevention unit may be opened. Thus, when a short circuit occurs due to damage of the capacitor unit, the short circuit maybe effectively prevented through the short-circuit prevention unit.

The filter device 100 according to the present embodiments may further include at least one of the inductor unit 130 and the resistor unit 140. The inductor unit 130 and the resistor unit 140 may be one or more. The inductor unit 130 may include at least one inductor. The resistor unit 140 may include at least one resistor.

Accordingly, the filter device 100 may further include at least one of at least one inductor unit 130 including at least one inductor and at least one resistor unit 140 including at least one resistor.

In one example, the filter device 100 may be an LC filter, when it further includes the inductor unit 130. That is, the series-connected capacitor unit 110 and short-circuit prevention unit 120, and the inductor unit 130 may constitute an LC filter.

In particular, when the capacitor unit 110 includes a first capacitor unit and a second capacitor unit, and the filter device 100 further includes the inductor unit 130, then the first capacitor unit, the second capacitor unit, and the inductor unit 130 may constitute a π-shaped LC filter. That is, a first capacitor unit and a first short-circuit prevention unit connected in series, a second capacitor unit and a second short-circuit prevention unit connected in series, and the inductor unit 130 may constitute a π-shaped LC filter.

In another example, the filter device 100 may be an RLC filter, when it further includes the inductor unit 130 and the resistor unit 140. That is, the capacitor unit 110 and the short-circuit prevention unit 120 connected in series, the inductor unit 130, and the resistor unit 140 may constitute an RLC filter.

In addition, the filter device 100 according to the present embodiments may include at least one of an EMI filter and an EMC filter.

The types and shapes of the filter devices according to the present embodiments are merely exemplary, and the filter devices according to the present embodiments may include any type and shape of filters.

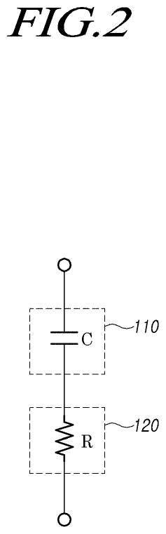

FIG. 2 is a detailed block diagram illustrating a capacitor unit and a short-circuit prevention unit according to the present embodiments.

Referring to FIG. 2, the capacitor unit 110 may include a capacitor C. The short-circuit prevention unit 120 may include a resistor R or the like. In particular, the short-circuit prevention unit 120 may include a resistor R connected in series to the capacitor C.

The capacitor C and the resistor R may be one or more. Hereinafter, it will be described with a case in which the capacitor C and the resistor R are one, but the disclosure is not limited thereto and may be applied to a case in which the capacitor C and the resistor R are two or more.

Specifically, the capacitor C of the capacitor unit 110 and the resistor R of the short-circuit prevention unit 120 may be connected to each other. For example, the capacitor C of the capacitor unit 110 and the resistor R of the short-circuit prevention unit 120 may be connected in series. That is, the capacitor C of the capacitor unit 110 and the resistor R of the short-circuit prevention unit 120 may be positioned on the same voltage path or current path, and may be positioned to be connected to each other in a line.

When the capacitor C of the capacitor unit 110 is short-circuited, the resistor R of the short-circuit prevention unit 120 may block a short-circuit current by changing a value of the resistor R so that the impedance of the series-connected capacitor unit 110 and short-circuit prevention unit 120 increases. Here, the overcurrent, that is, the short-circuit current, maybe a current capable of changing an initial resistance (or a first resistance) of the resistor R of the short-circuit prevention unit 120.

That is, when the capacitor C of the capacitor unit 110 from among the capacitor C of the capacitor unit 110 and the resistor R of the short-circuit prevention unit 120, which are connected in series, is short-circuited to generate an overcurrent, i.e., a short-circuit current, the resistor R of the short-circuit prevention unit 120 may block the short-circuit current by changing the impedance formed through the capacitor C of the capacitor unit 110 and the resistor R of the short-circuit prevention unit 120, which are connected in series.

Here, the resistor R of the short-circuit prevention unit 120 may be fused after the resistance gradually increases with respect to the first resistance.

In particular, the first resistance may be a resistance of the resistor R of the short-circuit prevention unit 120, when the capacitor C of the capacitor unit 110 and the resistor R of the short-circuit prevention unit 120, which are connected in series, are normal, i.e., when the capacitor C of the capacitor unit 110 is not short-circuited. Accordingly, when the capacitor C of the capacitor unit 110 and the resistor R of the short-circuit prevention unit 120, which are connected in series, are normal, that is, when the capacitor C of the capacitor unit 110 is not short-circuited, the filter device 100 may filter noise through the capacitor C of the capacitor unit 110 and the resistor R with the first resistance of the short-circuit prevention unit 120, which are connected in series.

Here, the first resistance may be 0Ω. Accordingly, when the capacitor C of the capacitor unit 110 is not short-circuited, the filter device 100 may filter noise through the capacitor C of the capacitor unit 110 and the resistor R with 0Ω of the short-circuit prevention unit 120. Alternatively, when the capacitor C of the capacitor unit 110 is short-circuited, the resistor R of the short-circuit prevention unit 120 may be fused after the resistance gradually increases with respect to 0Ω.

The resistor R of the short-circuit prevention unit 120 may include a jumper-type chip resistor.

As described above, the filter device according to the present embodiments may perform a filtering operation through the capacitor of the capacitor unit and the resistor of the short-circuit prevention unit, when it is in a normal state. Alternatively, when the capacitor of the capacitor unit is short-circuited to generate a short-circuit current, the short-circuit prevention unit may be fused after the resistance of the resistor of the short-circuit prevention unit gradually increases with respect to the first resistance which is the normal-state resistance. As a result, the voltage path or current path of the capacitor of the capacitor unit and the resistor of short-circuit prevention unit, which are connected in series, may be opened. Thus, when a short circuit occurs due to damage of the capacitor of the capacitor unit, the short circuit maybe effectively prevented through the resistor of the short-circuit prevention unit.

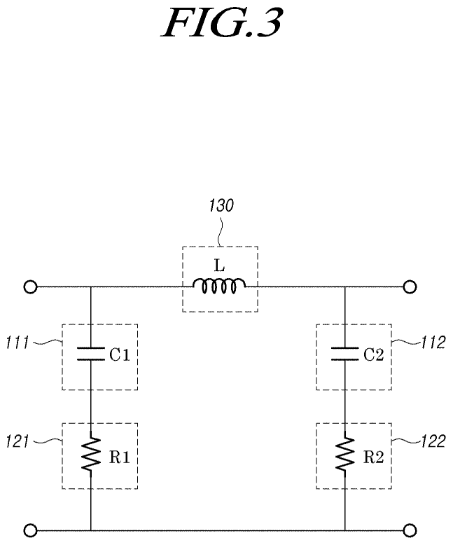

FIGS. 3 to 5 are circuit diagrams specifically illustrating a filter device according to the present embodiments.

Referring to FIGS. 3 to 5, the capacitor unit 110, the short-circuit prevention unit 120, the inductor unit 130, and the resistor unit 140 may be one or more. In particular, the capacitor unit 110 may include at least one capacitor. The short-circuit prevention unit 120 may include at least one resistor. The inductor unit 130 may include at least one inductor. The resistor unit 140 may include at least one resistor.

Here, the resistor of the short-circuit prevention unit 120 may include a jumper-type chip resistor with a resistance of 0Ω.

The capacitor of the capacitor unit 110 may include a general-purpose multi-layer ceramic condenser (MLCC).

Referring to FIG. 3, the filter device 100 according to the present embodiments may be a π-shaped LC filter.

The capacitor unit 110 may include a first capacitor unit 111 and a second capacitor unit 112. The first capacitor unit 111 may include a first capacitor C1, and the second capacitor unit 112 may include a second capacitor C2.

The short-circuit prevention unit 120 may include a first short-circuit prevention unit 121 and a second short-circuit prevention unit 122. The first short-circuit prevention unit 121 may include a first resistor R1, and the second short-circuit prevention unit 122 may include a second resistor R2.

The inductor unit 130 may include an inductor L.

The first capacitor C1 of the first capacitor unit 111 and the first resistor R1 of the first short-circuit prevention unit 121 may be connected in series, and the second capacitor C2 of the second capacitor unit 112 and the second resistor R2 of the second short-circuit prevention unit 122 may be connected in series. The first capacitor C1 of the first capacitor unit 111 and the first resistor R1 of the first short-circuit prevention unit 121, which are connected in series, and the second capacitor C2 of the second capacitor unit 112 and the second resistor R2 of the second short-circuit prevention unit 122, which are connected in series, maybe connected in parallel. The inductor L of the inductor unit 130 may be connected to one side of the first capacitor C1 of the first capacitor unit 111 and one side of the second capacitor C2 of the second capacitor unit 112.

The filter device including a π-shaped LC filter according to the present embodiments may perform a filtering operation through the first capacitor, the second capacitor, the first resistor, the second resistor and the inductor, when it is in a normal state. Alternatively, when the first capacitor out of the first capacitor and the second capacitor is short-circuited to generate a short-circuit current, the short-circuit prevention unit may be fused after the resistance of the first resistor connected in series to the first capacitor gradually increases with respect to 0Ω. As a result, the voltage path or current path of the first capacitor and the first resistor connected in series may be opened. Thus, when a short circuit occurs due to damage of the first capacitor, the short circuit may be effectively prevented through the first resistor.

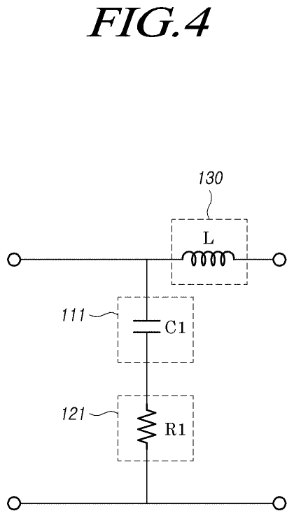

Referring to FIG. 4, the filter device 100 according to the present embodiments may be an LC filter.

The capacitor unit 110 may include a first capacitor unit 111. The first capacitor unit 111 may include a first capacitor C1. The short-circuit prevention unit 120 may include a first short-circuit prevention unit 121. The first short-circuit prevention unit 121 may include a first resistor R1. The inductor unit 130 may include an inductor L.

The first capacitor C1 of the first capacitor unit 111 and the first resistor R1 of the first short-circuit prevention unit 121 may be connected in series. The inductor L of the inductor unit 130 may be connected to one side of the first capacitor C1 of the first capacitor unit 111.

The filter device including an LC filter according to the present embodiments may perform a filtering operation through the first capacitor, the first resistor, and the inductor, when it is in a normal state. Alternatively, when the first capacitor is short-circuited to generate a short-circuit current, the short-circuit prevention unit may be fused after the resistance of the first resistor connected in series to the first capacitor gradually increases with respect to 0Ω. As a result, the voltage path or current path of the first capacitor and the first resistor connected in series may be opened. Thus, when a short circuit occurs due to damage of the first capacitor, the short circuit may be effectively prevented through the first resistor.

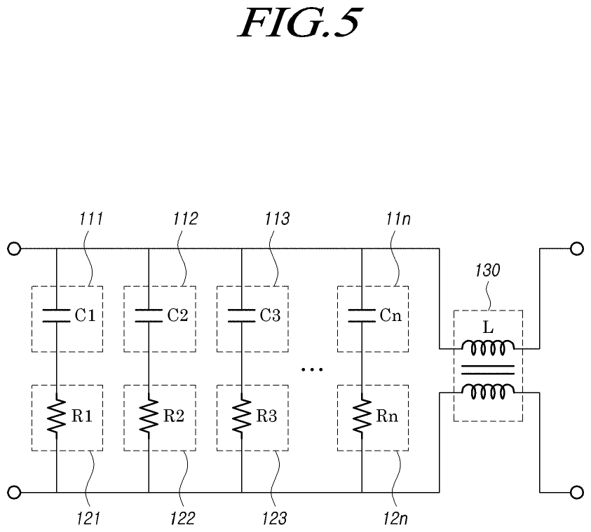

Referring to FIG. 5, in the filter device 100 according to the present embodiments, a plurality of series-connected capacitor units 110 and short-circuit prevention units 120 may be provided in parallel.

The capacitor unit 110 may include a first capacitor unit 111 to an nth capacitor unit 11n. The first capacitor unit 111 may include a first capacitor C1, and the nth capacitor unit 11n may include an nth capacitor Cn.

The short-circuit prevention unit 120 may include a first short-circuit prevention unit 121 to an nth short-circuit prevention unit 12n. The first short-circuit prevention unit 121 may include a first resistor R1, and the nth short-circuit prevention unit 12n may include an nth resistor Rn.

The inductor unit 130 may include an inductor L.

The first capacitor C1 of the first capacitor unit 111 and the first resistor R1 of the first short-circuit prevention unit 121 may be connected in series, and the nth capacitor Cn of the nth capacitor unit 11n and the nth resistor Rn of the nth short-circuit prevention unit 12n may be connected in series. The first capacitor C1 of the first capacitor unit 111 and the first resistor R1 of the first short-circuit prevention unit 121 connected in series, and the nth capacitor Cn of the nth capacitor unit 11n and the nth resistor Rn of the nth short-circuit prevention unit 12n connected in series, may be connected in parallel. The inductor L of the inductor unit 130 may be connected to one side of the first capacitor C1 of the first capacitor unit 111 and one side of the nth capacitor Cn of the nth capacitor unit 11n.

The filter device including a plurality of capacitor units and a plurality of short-circuit prevention units, which are connected in series and provided in parallel, according to the present embodiments may perform a filtering operation through the first capacitor to the nth capacitor, the first resistor to the nth resistor, and the inductor, when it is in a normal state. Alternatively, when the first capacitor out of the first capacitor to the nth capacitor is short-circuited to generate a short-circuit current, the short-circuit prevention unit maybe fused after the resistance of the first resistor connected in series to the first capacitor gradually increases with respect to 0Ω. As a result, the voltage path or current path of the first capacitor and the first resistor connected in series may be opened. Thus, when a short circuit occurs due to damage of the first capacitor, the short circuit may be effectively prevented through the first resistor.

The filter devices according to the present embodiments described above with reference to FIGS. 3 to 5 are merely exemplary embodiments, and may be applied to any other filter types. In addition, the filter device according to the present embodiments, if located between an input power source and a power converter (e.g., an inverter), may filter the electrical energy (e.g., (AC and/or DC) voltage and/or current, etc.) of the input power source, as well as the switching noise introduced from the power converter (e.g., the inverter).

As described above, in the filter device according to the present embodiments, the capacitor of the capacitor unit may be a general-purpose multi-layer ceramic condenser (MLCC), and the resistor of the short-circuit prevention unit maybe a jumper-type chip resistor. In this case, by implementing the general-purpose MLCC and the jumper-type chip resistor in series, the filter device may not only filter noise in normal times, but also implement a battery short-circuit prevention function at low cost due to the fusing operation of the jumper-type chip resistor even if a short circuit occurs in the general-purpose MLCC. In particular, in the filter device according to the present embodiments, even if the jumper-type chip resistor is not fused, the characteristics change in the direction in which the impedance increases, so that the short-circuit current caused by the short circuit of the general-purpose MLCC may be effectively blocked. That is, the filter device according to the present embodiments may have a function of preventing a short circuit when a capacitor is damaged while using a low-cost MLCC.

Further, in the filter device according to the present embodiments, when the capacitor of the capacitor unit is a general-purpose multi-layer ceramic condenser (MLCC), and the resistor of the short-circuit prevention unit is a jumper-type chip resistor, not only cost reduction is possible, but also product misintercalation and management points may be viewed in a bird's eye with one BOM in the mass production line.

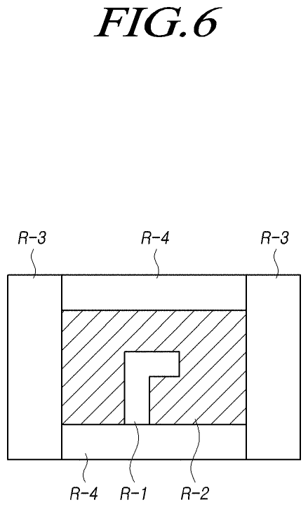

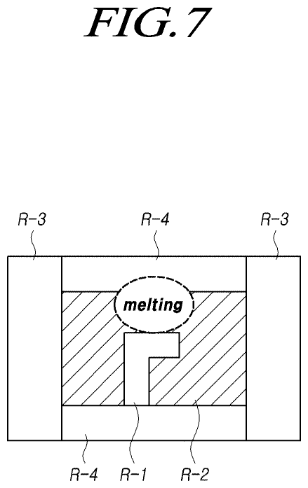

FIGS. 6 and 7 are diagrams specifically illustrating a resistor of a short-circuit prevention unit according to the present embodiments.

Referring to FIG. 6, the resistor R of the short-circuit prevention unit 120 according to the present embodiments may be a jumper-type chip resistor.

The resistor R of the short-circuit prevention unit 120 may include a laser trimming groove R-1, a resistor body R-2, an electrode R-3, an alumina substrate R-4, and the like.

In particular, the resistance may be adjusted by adjusting the laser trimming groove R-1 through laser cutting.

The laser trimming groove R-1 may be formed to have an initial resistance of 0Ω. Here, 0Ω may be a value having a predetermined error range. In particular, the predetermined error range may be 5%, but is not limited thereto and may be modified according to the specifications of the filter device.

Therefore, when the capacitor C of the capacitor unit 110 and the resistor R of the short-circuit prevention unit 120 connected in series are normal, i.e., when the capacitor C of the capacitor unit 110 is not short-circuited to generate no overcurrent, the filter device 100 may filter noise through the capacitor C of the capacitor unit 110 and the resistor R with a resistance of 0Ω of the short-circuit prevention unit 120, which are connected in series.

Referring to FIG. 7, when the capacitor C of the capacitor unit 110 among the capacitor C of the capacitor unit 110 and the resistor R of the short-circuit prevention unit 120 connected in series is short-circuited to generate an overcurrent, i.e., a short-circuit current, the resistor R of the short-circuit prevention unit 120 may be melted and cut off. That is, when the capacitor C of the capacitor unit 110 is short-circuited to generate an overcurrent, i.e., a short-circuit current, the resistor R of the short-circuit prevention unit 120 may be fused after the periphery of the laser trimming groove R-1 is melted and the resistance gradually increases with respect to 0Ω.

In other words, the resistor R of the short-circuit prevention unit 120 may open the circuit of the filter device 100 after being melted by the overcurrent. The current maximum Imax may be 2 A and 2 sec, but is not limited thereto and may be modified according to the specifications of the filter device.

Here, the resistance maximum Rmax of the jumper-type chip resistor maybe 50 mΩ, but is not limited thereto and may be modified according to the specifications of the filter device.

Here, the test voltage may be less than at least one of rated voltage (current)×2.5, 2 s, and maximum overload voltage, but is not limited thereto and may be modified according to the specifications of the filter device.

As such, the resistor of the short-circuit prevention unit according to the present embodiments may provide a short-circuit prevention circuit when a short circuit occurs due to damage of a chip capacitor.

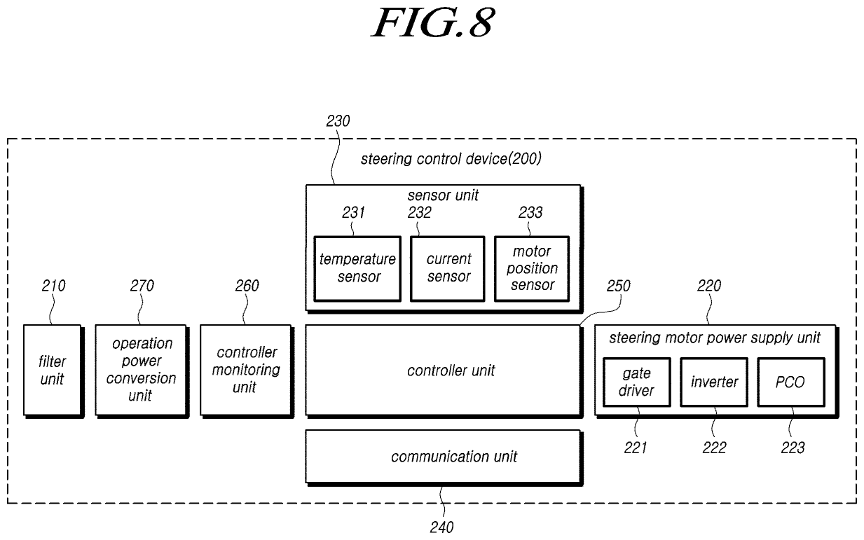

FIG. 8 is a detailed block diagram illustrating a steering control device according to the present embodiments.

Referring to FIG. 8, the steering control device 200 according to the present embodiments may include at least one of a filter unit 210 and a steering motor power supply unit 220.

For example, the steering control device 200 according to the present embodiments may include the filter unit 210 for filtering noise of electrical energy; and the steering motor power supply unit 220 for generating an assist steering force by converting the filtered electrical energy based on a steering motor control signal, and controlling a steering motor based on the assist steering force. The filter unit 210 may include a capacitor unit and a short-circuit prevention unit, and the capacitor unit and the short-circuit prevention unit may be connected in series. When the capacitor unit is short-circuited, the short-circuit prevention unit may block a short-circuit current by changing an impedance formed through the capacitor unit and the short-circuit prevention unit connected in series.

Specifically, the filter unit 210 may be the same component as the filter device 100 described above with reference to FIGS. 1 to 7.

The capacitor unit 110 may include a capacitor C, and the short-circuit prevention unit 120 may include a resistor R connected in series to the capacitor C.

Further, when the capacitor C of the capacitor unit 110 is short-circuited, the resistor R of the short-circuit prevention unit 120 may change its resistance so that the impedance of the capacitor unit 110 and the short-circuit prevention unit 120 connected in series increases, to block the short-circuit current.

Further, the resistor R of the short-circuit prevention unit 120 maybe fused after the resistance gradually increases with respect to a first resistance.

Further, the first resistance may be 0Ω.

Further, when the capacitor C of the capacitor unit 110 is not short-circuited, the noise may be filtered through the capacitor C of the capacitor unit 110 and the resistor R with 0Ω of the short-circuit prevention unit.

Further, the filter unit 210 may further include at least one of the inductor unit 130 including an inductor L and the resistor unit 140 including the resistor R.

Further, when the capacitor unit 110 includes the first capacitor unit 111 and the second capacitor unit 112, and the filter unit 210 further includes the inductor unit 130, then the first capacitor unit 111, the second capacitor unit 112 and the inductor unit 130 may constitute a π-shaped LC filter.

As for the filter unit 210, the description of the filter device 100 described above with reference to FIGS. 1 to 7 may be applied substantially the same, and thus a duplicate description will be omitted below.

The steering motor power supply unit 220 may be connected to the filter unit 210 to receive filtered electrical energy. The steering motor power supply unit 220 may be connected to a controller unit 250 to receive a steering motor control signal. The steering motor power supply unit 220 may convert the filtered electrical energy based on the steering motor control signal to generate an assist steering force, and may control the steering motor based on the assist steering force.

For example, when the filter unit 210 is normal, the steering motor power supply unit 220 may convert the filtered electrical energy based on the steering motor control signal to generate an assist steering force, and may control the steering motor based on the assist steering force. On the other hand, when the capacitor C of the filter unit 210 is short-circuited and the resistor R is fused as the resistance of the resistor R gradually increases, the steering motor power supply unit 220 may convert electrical energy provided from the input power source based on the steering motor control signal to generate an assist steering force, and may control the steering motor or stop the operation based on the assist steering force.

Further, the steering motor power supply unit 220 may include a gate driver 221, an inverter 222, and a phase disconnector (PCO) 223.

The gate driver 221 may receive a steering motor control signal from the controller unit 250, generate a gate signal based on this, and provide it to the inverter 222. The inverter 222 may generate an assist steering force by converting the filtered electrical energy of the filtering unit according to the gate signal. The phase disconnector (e.g., a breaker or disconnector) 223 may be positioned between the inverter 222 and the steering motor, and may supply or block the assist steering force provided from the inverter 222 to the steering motor.

The steering control device 200 according to the present embodiments may further include at least one of a sensor unit 230, a communication unit 240, the controller unit 250, a controller monitoring unit 260, and an operation power conversion unit 270.

The sensor unit 230 may include at least one of a temperature sensor 231, a current sensor 232, and a motor position sensor 233, but is not limited thereto, and may include any sensor as long as it can measure a state of the steering system (or the steering control device).

The temperature sensor 231 may measure the temperature of the steering control device and provide temperature information to the controller unit 250. The current sensor 232 may measure an assist current (or an assist steering force) provided from the steering motor power supply unit 220 to the steering motor, to provide the assist current information to the controller unit 250. The motor position sensor 233 may measure the position of the steering motor and provide position information of the steering motor to the controller unit 250.

The communication unit 240 may include at least one of an internal communication unit and an external communication unit. The internal communication unit, when there are multiple steering control devices, maybe connected to other steering control devices to receive or provide information from/to each other. The external communication unit may be connected to a vehicle to receive vehicle state information (e.g., vehicle speed information, etc.) from the vehicle or provide information related to the steering system to the vehicle.

The controller unit 250 may be connected to each component of the steering control device to provide information or receive information to control the operation.

For example, based on at least one of torque information of the steering wheel, steering angle information of the steering wheel, temperature information, assist current information, steering motor position information, vehicle status information (e.g., vehicle speed information), input power status information, short circuit (or overcurrent) status information, and status information of the steering motor, the controller unit 250 may generate a steering motor control signal and provide it to the gate driver, or may generate a separation/connection control signal (e.g., a clutch control signal) and provide it to a separation/connection mechanism.

The controller unit 250 may include a microcontroller, but is not limited thereto, and may include any device (or computer) as long as it is a device (or computer) capable of processing (or executing and computing) a program.

The controller monitoring unit 260 may be connected to the controller unit 250. The controller monitoring unit 260 may monitor the operating state of the controller unit 250. For example, the controller unit 250 may provide a watchdog signal to the controller monitoring unit 260. In addition, the controller monitoring unit 260 maybe cleared based on the watchdog signal provided from the controller unit 250, or may generate a reset signal and provide it to the controller unit 250.

The controller monitoring unit 260 may include a watchdog, but is not limited thereto, and may include any device as long as it is a device that can monitor the controller unit. In particular, the watchdog may include a window watchdog having a deadline, i.e., having a start and an end.

The operation power conversion unit 270 may be connected to the filter unit 210. The operation power conversion unit 270 may convert the filtered electrical energy of the filter unit 210 to generate an operating voltage for each component of a steering assist device. The operation power conversion unit 270 may include at least one of a DC-DC converter and a regulator, but is not limited thereto, and may include any device as long as it can convert an output of a power protection module to generate operating voltages for each component of the steering control device.

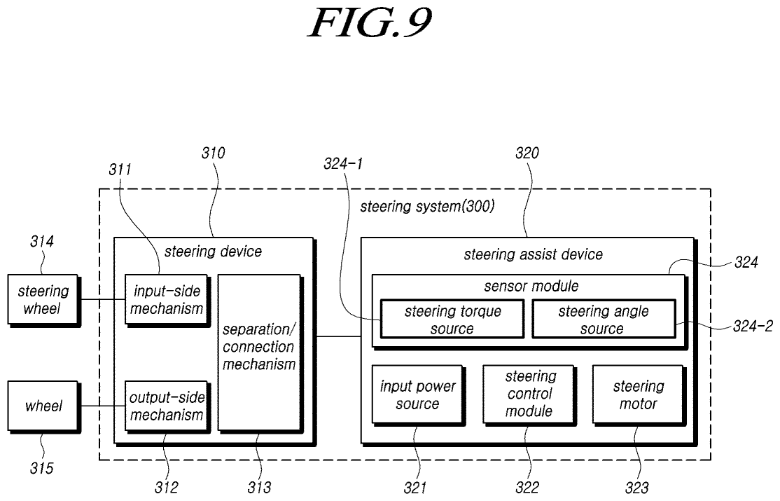

FIG. 9 is an overall block diagram illustrating a steering system according to the present embodiments.

Referring to FIG. 9, a steering system 300 according to the present embodiments may include at least one of a steering device 310 and a steering assist device 320.

The steering device 310 may change a steering angle of a wheel 315 based on a steering force (or a rotational force, etc.) applied to a steering wheel 314. The steering device 310 may include an input-side mechanism 311 and an output-side mechanism 312. The steering device 310 may further include a separation/connection mechanism 313 and the like.

The input-side mechanism 311 may be connected to the steering wheel 314. The input-side mechanism 311 may rotate in a rotational direction of the steering wheel 314 or in a direction opposite to the rotational direction of the steering wheel 314. The input-side mechanism 311 may include, but is not limited to, a steering shaft connected to the steering wheel 314, and may include any mechanism (or device) as long as it can rotate (or move) in a rotational direction of the steering wheel or in a direction opposite to the rotational direction of the steering wheel.

The output-side mechanism 312 maybe connected to the input-side mechanism 311 by at least one of electrical and mechanical manners. The output-side mechanism 312 may be connected to the wheel 315 to change a steering angle (or movement, etc.) of the wheel 315. The output-side mechanism 312 may include at least one of a pinion, a rack, a tie rod, and a knuckle arm, but is not limited thereto, and may include any mechanism (or device) as long as it can change the steering angle (or, movement, etc.) of the wheel.

The separation/connection mechanism 313 maybe connected to the input-side mechanism 311 and the output-side mechanism 312. The separation/connection mechanism 313 may mechanically or electrically connect or disconnect (or separate) the input-side mechanism 311 and the output-side mechanism 312. The separation/connection mechanism 313 may include a clutch, but is not limited thereto, and may include any mechanism (or device) as long as it can mechanically or electrically connect or disconnect (or separate) the input-side mechanism and the output-side mechanism.

The steering device 310 according to the present embodiments may include at least one of a steering device in which the input-side mechanism and the output-side mechanism are mechanically connected, a steering device (or a steer-by-wire, SbW) in which the input-side mechanism and the output-side mechanism are electrically connected, and a steering device (or an SbW including a clutch) in which the input-side mechanism and the output-side mechanism are connected to the separation/connection mechanism.

Although the steering wheel 314 and the wheel 315 are illustrated as not included in the steering device 310, the disclosure is not limited thereto, and they may be included in the steering device 310.

The steering assist device 320 may be connected to the steering device 310. The steering assist device 320 may provide an assist steering force to the steering device 310. The steering assist device 320 may include an electronic control unit (ECU), but is not limited thereto, and may include any control device (or system) as long as it is a device (or system) that can electronically control it.

The steering assist device 320 according to the present embodiments may include at least one of an input power source 321, a steering control module 322, a steering motor 323, and a sensor module 324.

The input power source 321 may include at least one of a DC power source and an AC power source. In particular, the DC power source may include a battery or the like, but is not limited thereto, and may include any power source as long as it can provide DC power.

The steering control module 322 may be connected to the input power source 321. The steering control module 322 may receive electrical energy from the input power source 321, filter the noise of the electrical energy, convert the filtered electrical energy based on the steering motor control signal to generate an assist steering force, and control the steering motor 323 based on the assist steering force.

As for the steering control module 322, the description of the steering control device 200 described above with reference to FIG. 8 maybe applied substantially the same, and thus a redundant description will be omitted below.

The sensor module 324 may include at least one sensor.

The sensor may include at least one of a steering torque sensor 324-1 and a steering angle sensor 324-2, but is not limited thereto, and may include any sensor as long as it can measure the state of the vehicle and the steering state of the vehicle.

The steering torque sensor 324-1 may measure the steering torque of the steering wheel and provide torque information of the steering wheel to the steering control module 322. Further, the steering angle sensor 324-2 may measure a steering angle of the steering wheel and provide steering angle information of the steering wheel to the steering control module 322.

The steering control module 322 may generate a steering motor control signal based on at least one of steering torque information and steering angle information, and convert the filtered electrical energy according to the steering motor control signal to generate an assist steering force, and may control the steering motor 323 based on the assist steering force.

The steering motor 323 may be connected to the steering control module 322. The steering motor 323 may assist the steering of the steering device 310 by operating based on the assist steering force provided from the steering control module 322.

The steering motor 323 may include, but is not limited to, at least one of a single winding-type motor and a dual winding-type motor, and may include any motor as long as it can assist steering of the steering device.

The steering motor 323 may include at least one of a three-phase type motor and a five-phase type motor, but is not limited thereto, and may include any motor as long as it can assist steering of the steering device.

Hereinafter, a steering control method according to the present embodiments will be described with reference to the accompanying drawings. In particular, as for the filter device, the steering control device, and the steering system according to the present embodiments described above with reference to FIGS. 1 to 9, the overlapping descriptions will be omitted below for the sake of brevity of description.

The steering control method according to the present embodiments maybe performed through the filter device, the steering control device, and the steering system.

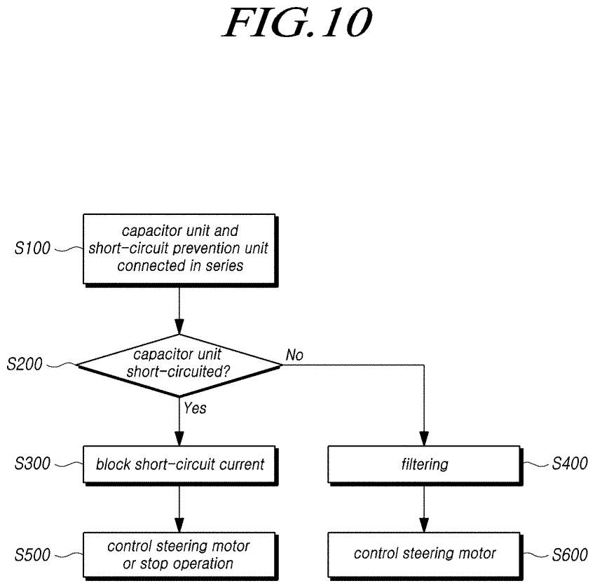

FIG. 10 is an overall flowchart illustrating a steering control method according to the present embodiments.

Referring to FIG. 10, first, a capacitor unit and a short-circuit prevention unit may be connected in series (S100).

Thereafter, it may be determined whether the capacitor unit is short-circuited (S200). Here, whether the capacitor unit is short-circuited may be determined by the overcurrent, i.e., the short-circuit current, which is generated as the capacitor unit is short-circuited.

Thereafter, if the capacitor unit is short-circuited, the short-circuit prevention unit may block the short-circuit current by changing an impedance formed through the series-connected capacitor unit and short-circuit prevention unit (S300).

Here, the capacitor unit may include a capacitor, and the short-circuit prevention unit may include a resistor connected in series to the capacitor.

In step S300, when the capacitor of the capacitor unit is short-circuited, the resistor of the short-circuit prevention unit may block the short-circuit current by changing its resistance such that the impedance of the series-connected capacitor unit and short-circuit prevention unit increases.

Here, the resistor of the short-circuit prevention unit may be fused after the resistance gradually increases with respect to the first resistance. In particular, the first resistance may be 0Ω.

Thereafter, an assist steering force may be generated by converting electrical energy provided from an input power source based on the steering motor control signal, and the steering motor may be controlled or the operation stopped based on the assist steering force (S500).

Further, when the capacitor of the capacitor unit is not short-circuited, noise of the electrical energy may be filtered through the capacitor unit and the short-circuit prevention unit connected in series (S400).

In step S400, when the capacitor of the capacitor unit is not short-circuited, noise of the electrical energy may be filtered through the capacitor of the capacitor unit and a resistor with 0Ω of the short-circuit prevention unit.

Thereafter, an assist steering force may be generated by converting the filtered electrical energy based on the steering motor control signal, and the steering motor may be controlled based on the assist steering force (S600).

Here, at least one of an inductor unit including an inductor and a resistor unit including a resistor may be further included. Thus, when the capacitor unit includes a first capacitor unit and a second capacitor unit, and the inductor unit is further included, the first capacitor unit, the second capacitor unit, and the inductor unit may constitute a π-shaped LC filter.

The foregoing description is merely illustrative of the technical spirit of the present disclosure, and various modifications and variations may be made without departing from the essential characteristics of the present disclosure by those skilled in the art to which the present disclosure pertains. In addition, the present embodiments are not intended to limit the technical spirit of the present disclosure, but rather to explain, so the scope of the present technical spirit is not limited by these embodiments. The protection scope of the present disclosure should be interpreted by the following claims, and all technical ideas within the scope equivalent thereto should be construed as being included in the scope of the present disclosure.

### CROSS-REFERENCE TO RELATED APPLICATION

The instant patent application claims priority under 35 U.S.C. 119(a) to Korean Patent Application No. 10-2019-0148222, filed on Nov. 19, 2019, in the Korean Intellectual Property Office, the disclosure of which is herein incorporated by reference in its entirety. The present patent application claims priority to other applications to be filed in other countries, the disclosures of which are also incorporated by reference herein in their entireties.

1. A filter device for filtering noise, including a capacitor unit and a short-circuit prevention unit,
wherein the capacitor unit and the short-circuit prevention unit are connected in series, and
wherein when the capacitor unit is short-circuited, the short-circuit prevention unit blocks a short-circuit current by changing an impedance formed through the capacitor unit and the short-circuit prevention unit connected in series.

2. The filter device of claim 1, wherein the capacitor unit includes a capacitor, and the short-circuit prevention unit includes a resistor connected in series to the capacitor.

3. The filter device of claim 2, wherein when the capacitor of the capacitor unit is short-circuited, the resistor of the short-circuit prevention unit blocks the short-circuit current as a resistance is changed to increase the impedance of the capacitor unit and the short-circuit prevention unit connected in series.

4. The filter device of claim 3, wherein the resistor of the short-circuit prevention unit is fused after the resistance gradually increases with respect to a first resistance.

5. The filter device of claim 4, wherein the first resistance is 0Ω.

6. The filter device of claim 5, wherein when the capacitor of the capacitor unit is not short-circuited, the noise is filtered through the capacitor of the capacitor unit and the resistor with 0Ω of the short-circuit prevention unit.

7. The filter device of claim 1, further comprising at least one of an inductor unit including an inductor and a resistor unit including a resistor.

8. The filter device of claim 7, wherein when the capacitor unit includes a first capacitor unit and a second capacitor unit, and the filter device further includes the inductor unit, the first capacitor unit, the second capacitor unit, and the inductor unit constitute a π-shaped LC filter.

9. A steering control device, comprising:
a filter unit filtering noise of electrical energy; and
a steering motor power supply unit converting the filtered electrical energy based on a steering motor control signal to generate an assist steering force, and controlling a steering motor based on the assist steering force,
wherein the filter unit includes a capacitor unit and a short-circuit prevention unit,
wherein the capacitor unit and the short-circuit prevention unit are connected in series, and
wherein when the capacitor unit is short-circuited, the short-circuit prevention unit blocks a short-circuit current by changing an impedance formed through the capacitor unit and the short-circuit prevention unit connected in series.

10. The steering control device of claim 9, wherein the capacitor unit includes a capacitor, and the short-circuit prevention unit includes a resistor connected in series to the capacitor.

11. The steering control device of claim 10, wherein when the capacitor of the capacitor unit is short-circuited, the resistor of the short-circuit prevention unit blocks the short-circuit current as a resistance is changed to increase the impedance of the capacitor unit and the short-circuit prevention unit connected in series.

12. The steering control device of claim 11, wherein the resistor of the short-circuit prevention unit is fused after the resistance gradually increases with respect to a first resistance.

13. The steering control device of claim 12, wherein the first resistance is 0Ω.

14. The steering control device of claim 13, wherein when the capacitor of the capacitor unit is not short-circuited, the noise is filtered through the capacitor of the capacitor unit and the resistor with 0Ω of the short-circuit prevention unit.

15. The steering control device of claim 9, wherein the filter unit further includes at least one of an inductor unit including an inductor and a resistor unit including a resistor.

16. The steering control device of claim 15, wherein when the capacitor unit includes a first capacitor unit and a second capacitor unit, and the filter unit further includes the inductor unit, the first capacitor unit, the second capacitor unit, and the inductor unit constitute a π-shaped LC filter.
